(19) United States
(12) Patent Application Publication
(10) Pub. No.: US 2025/0194043 A1
(43) Pub. Date: Jun. 12, 2025

(54) COOLER

(71) Applicant: TILTA INC., Burbank, CA (US)

(72) Inventors: Shujin FU, Shenzhen (CN); Wenping ZENG, Shenzhen (CN); Kefeng ZHOU, Shenzhen (CN)

(21) Appl. No.: 18/973,407

(22) Filed: Dec. 9, 2024

(30) Foreign Application Priority Data
Dec. 12, 2023 (CN) 2023233870819

(51) Int. Cl. H05K 7/20; H02J 50/10

(52) U.S. Cl. CPC H05K 7/20172; H05K 7/2039; H02J 50/10

(57) ABSTRACT

The present disclosure presents a cooler including a housing, a control circuit board, a cooling component, a connecting piece, and a power supply interface. The control circuit board and the cooling component are housed within the housing, with the cooling component interconnected to the control circuit board. The power supply interface, electrically connected to the control circuit board, is positioned on and protrudes from the housing, while the connecting piece is mounted on one side of the housing.

### CROSS-REFERENCE TO RELATED APPLICATIONS

The present application for patent claims priority to and the benefit of pending Chinese Application No. 2023233870819, filed Dec. 12, 2023, and hereby expressly incorporated by reference herein as if fully set forth below in its entirety and for all applicable purposes.

### TECHNICAL FIELD

The present disclosure pertains to the technical realm of auxiliary heat dissipation for electronic devices, specifically a cooler for heat dissipation.

### INTRODUCTION

With the ubiquitous application of photography and videography in everyday life, an increasing number of individuals engage in photography as part of their daily routines. Consequently, there has been a surge in demand for advanced photography and videography capabilities in electronic devices. Presently, mobile phones on the market are equipped with increasingly optimized shooting functions, prompting many photographers to utilize electronic devices such as mobile phones and tablets for their shooting needs. However, a prevalent issue with these devices is overheating during operation, which can impede the user's shooting activities.

### BRIEF SUMMARY

The present disclosure is to introduce a cooler that can facilitate heat dissipation in electronic devices and mitigate the adverse effects of overheating on their normal functionality.

The present disclosure presents a cooler including a housing, a control circuit board, a cooling component, a connecting piece, and a power supply interface.

The control circuit board and the cooling component are housed within the housing, with the cooling component interconnected to the control circuit board. The power supply interface, electrically connected to the control circuit board, is positioned on and protrudes from the housing, while the connecting piece is mounted on one side of the housing.

In this disclosure, the cooler can be connected to an electronic device or an electronic device expansion frame via the connecting piece. The cooling component serves to aid in dissipating heat from the electronic device. The power supply interface is utilized to provide electrical power to the cooler.

### BRIEF DESCRIPTION OF THE DRAWINGS

FIG. 1 is a diagram illustrating a first perspective of a cooler according to some aspects of the disclosure.

FIG. 2 is a diagram illustrating a second perspective of the cooler according to some aspects of the disclosure.

FIG. 3 is a diagram illustrating an exploded view of the cooler according to some aspects of the disclosure.

FIG. 4 is a diagram illustrating a top view of the cooler according to some aspects of the disclosure.

FIG. 5 is a cross-sectional diagram of the plane A-A in FIG. 4.

FIG. 6 is a diagram illustrating the cooler being combined with an electronic device expansion frame.

### REFERENCE NUMERALS OF ELEMENTS IN THE DRAWINGS

100, cooler; 200, electronic device expansion frame; 300, filter; 400, power supply handle.
1, housing; 10, cover; 11, bottom housing; 12, first cover; 13, second cover; 14, first mounting groove; 15, second mounting groove; 16, positioning hole; 17, positioning pin; 18, air inlet; 19, air outlet.
2, control circuit board; 21, bypass through hole.
3, cooling component; 31, cooling element; 311, semiconductor chilling plate; 32, conductive piece; 321, first conductive piece; 322, second conductive piece; 33, fan module; 331, fan; 332, fan support frame; 333, mounting position.
4, connecting piece; 41, magnet.
5, power supply interface; 6, wireless charging module; 61, wireless charging coil; 7, switch button; 8, electronic contact pin; 9, positioning protrusion.

### DETAILED DESCRIPTION

The subsequent passages provide the technical solutions embodied within this application, drawing upon the illustrative figures. It is to be understood that the examples described in the present disclosures constitute but a fraction of the broader scope and are not exhaustive. Consequently, any alternative implementations derived by ordinary technicians in the relevant field, without the necessity for inventive ingenuity, are encompassed within the protective ambit of this application.

In the present disclosure, directional terminology (e.g., up, down, left, right, front, rear, etc.) serves exclusively to elucidate the relative positional arrangements and dynamic states among components within a specific orientational framework as depicted in the drawings. In the event of a change in this orientational framework, the directional designations will naturally align with the new configuration.

Furthermore, the utilization of ordinal indicators such as “first,” “second,” and so forth, in this application, is purely for descriptive clarity and cannot be misconstrued as signifying relative significance or implicitly indicating the number of technical features referenced. As such, expressions constrained by such ordinal designations may encompass one or more of the indicated features, either explicitly or implicitly. Moreover, the phrase “and/or” used throughout this document encompasses three distinct possibilities: Taking A and B as examples, it embraces the technical solution exclusive to A, the technical solution exclusive to B, as well as the technical solution that concurrently satisfies both A and B. Additionally, the integration of technical solutions across distinct examples is permissible, albeit contingent upon the feasibility of such integration by ordinary technicians in the field. In instances where the combined technical solutions conflict or are unfeasible, such integrations are deemed non-existent and thereby excluded from the scope of protection afforded by this application.

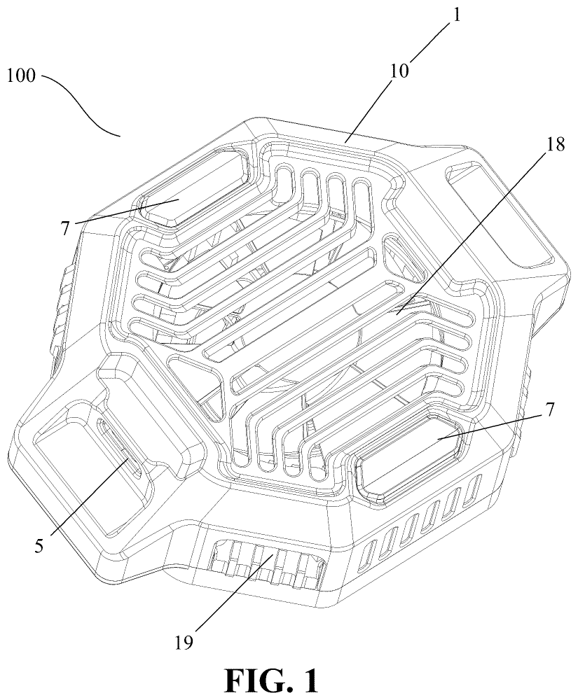

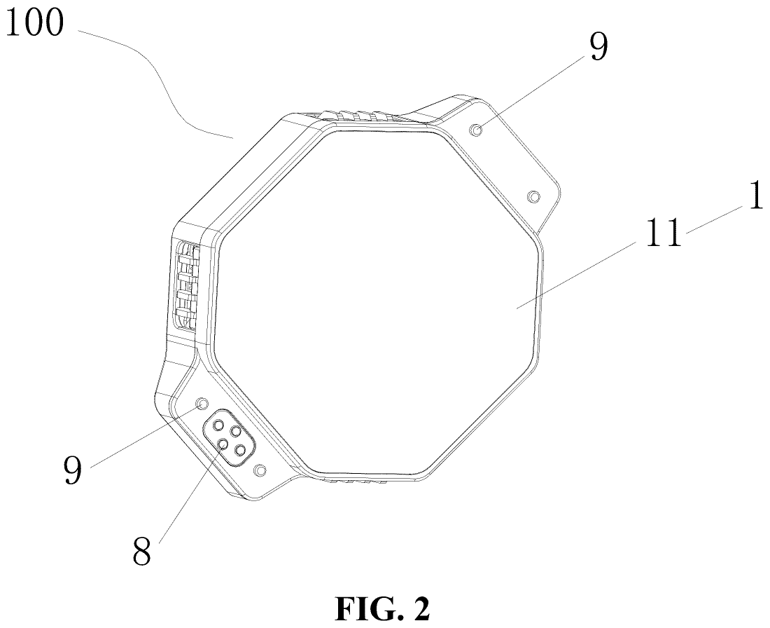

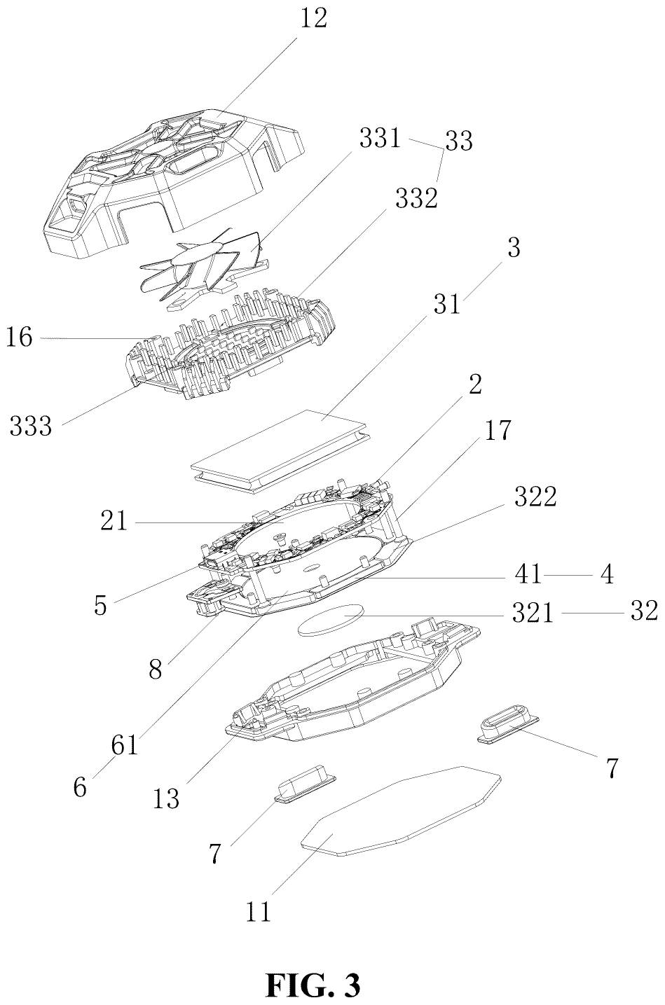

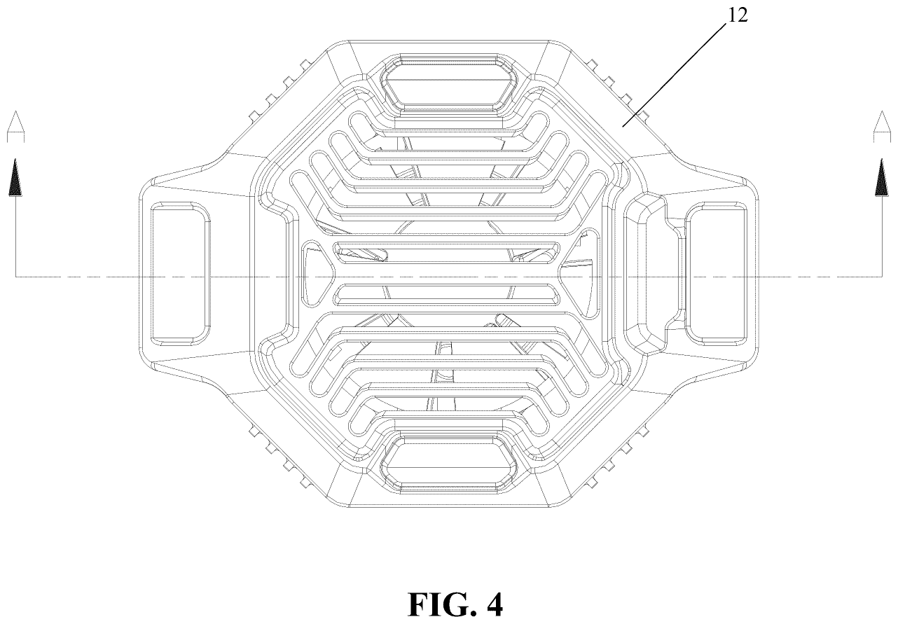

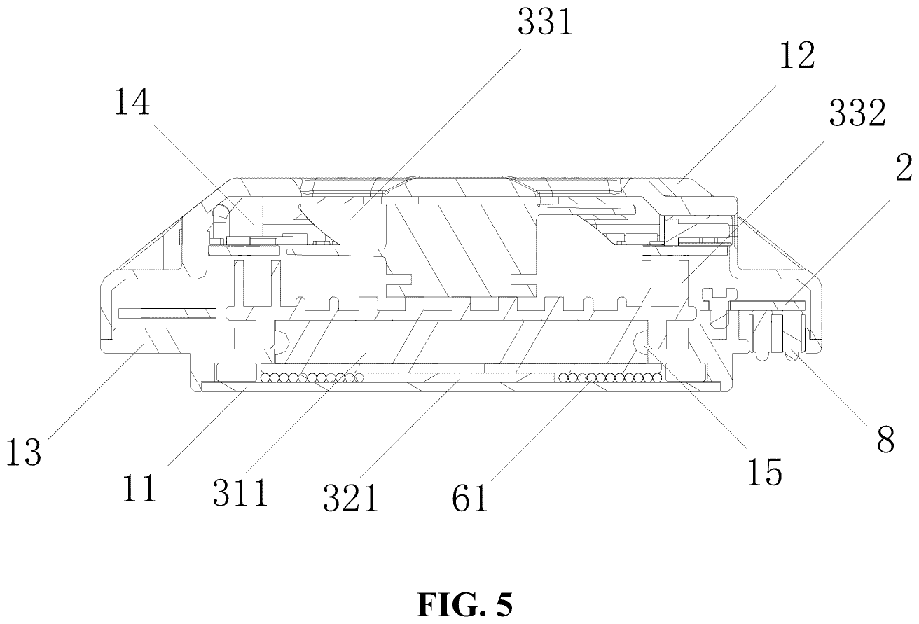

Referring to FIGS. 1-5, the present disclosure introduces a cooler 100 including a housing 1, a control circuit board 2, a cooling component 3, a connecting piece 4, and a power supply interface 5.

The control circuit board 2 and the cooling component 3 are provided within the housing 1, with the cooling component 3 being connected with the control circuit board 2. The power supply interface 5, which is electrically connected to the control circuit board 2, is mounted and exposed on the housing 1. The connecting piece 4 is affixed to one side of the housing 1.

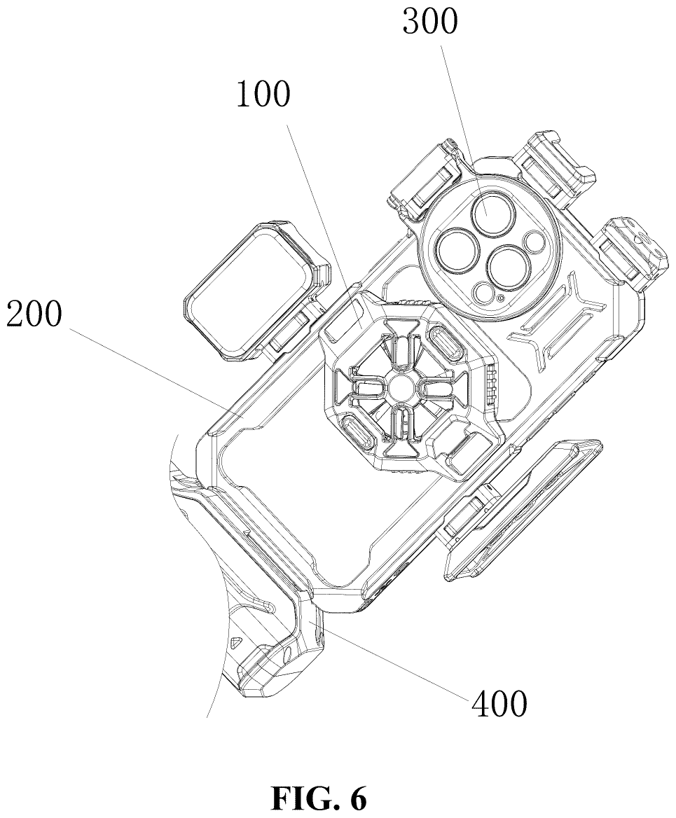

In the present disclosure, the cooler 100 can be connected to an electronic device or an electronic device expansion frame 200 (see FIG. 6) via the connecting piece 4. The cooling component 3 serves to aid in dissipating heat from the electronic device. The power supply interface 5 is utilized to provide electrical power to the cooler 100.

Furthermore, the cooling component 3 includes a cooling element 31, a conductive piece 32, and a fan module 33. Both the cooling element 31 and the fan module 33 are housed within the housing 1 and are electrically connected to the control circuit board 2. The cooling element 31 is positioned between the fan module 33 and the conductive piece 32. When powered on, the cooling element 31 generates cooling effect and applies it to the electronic device to facilitate heat dissipation. The fan module 33 is employed to dissipate heat and cool down both the cooling element 31 and the electronic device.

Furthermore, the cooling element 31 utilizes a semiconductor chilling plate 311, with a hot end facing the fan module 33 and a cold end facing the conductive piece 32. The cold end of a semiconductor chilling plate 311 produces cooling effect that is applied to the electronic device, while the heat generated at the hot end is dissipated by the fan module 33.

Furthermore, the conductive piece 32 includes a first conductive piece 321 and a second conductive piece 322. The first conductive piece 321 is adhered to the bottom of a wireless charging coil 61, while at least two second conductive pieces 322 are disposed around the periphery of the cooling element.

Furthermore, the conductive piece 32 can be crafted from thermally conductive silicone material. The thermally conductive silicone, in proximity to both the electronic device and the semiconductor chilling plate 311, facilitates heat exchange, thereby accelerating the cooling process of the electronic device.

Furthermore, the fan module 33 includes a fan 331 and a fan support frame 332; wherein the fan 331 is electrically connected to the control circuit board 2, while the fan support frame 332 is fixedly attached to the housing 1. A mounting position 333 is provided on one side of the fan support frame 332, and the fan 331 is securely fixed to the mounting position 333 and positioned close to the cooling element.

Furthermore, the control circuit board 2 is fixed at the mounting position 333, featuring a bypass through-hole 21 in the center; and the fan 331 is situated within this bypass through-hole 21, such that the control circuit board 2 surrounds the fan's periphery 331. In this example, the fan support frame 332 serves to support and secure the fan 331 and the control circuit board 2. Positioned centrally on the control circuit board 2, the fan 331 can effectively cool down the entire control circuit board 2.

Furthermore, the housing 1 includes a cover 10 and a bottom housing 11, fixedly connected; and wherein the connecting piece 4 is located inside the bottom housing 11, and the fan support frame 332 is fixedly attached to the cover 10.

Furthermore, the cover 10 includes a first cover 12 and a second cover 13, detachably connected; wherein the second cover 13 is fixedly connected to the bottom housing, forming a first mounting groove 14 among the first cover 12, fan support frame 332, and second cover 13; wherein the control circuit board 2 and fan module 33 are housed within this first mounting groove 14; and wherein a second mounting groove 15 is formed among the second cover 13, fan support frame 332, and bottom housing 11, housing the cooling element 31, conductive piece 32, and connecting piece 4. The first mounting groove 14 and the second mounting groove 15 serve to divide the housing 1 into two distinct chambers, facilitating the separate installation of various components. This configuration prevents interference among the components and enhances the overall structural stability of the product. It is noteworthy that the first cover 12 and the second cover 13 can be detachably connected either via latches or directly through screws.

Furthermore, the cooler 100 incorporates a wireless charging module 6, which is electrically interconnected with the control circuit board 2 and positioned on the opposite side of the cooling element 31 from the fan module 33, specifically at the cold end of the semiconductor chilling plate 311. The wireless charging module 6 utilizes a wireless charging coil 61. In the present disclosure, during the process of the wireless charging module 6 supplying power to an electronic device, if the temperature of either the electronic device or the wireless charging module 6 rises, the cold end of the cooling clement 31 dissipates heat from both, achieving a balanced temperature state.

Furthermore, the connecting piece 4 employs a ring-shaped arrangement of magnets 41 within the bottom housing 11. These magnets 41 and the second conductive piece 322 are spaced apart within the housing 1. In this application, the cooler 100 can be adsorbed onto an electronic device or an electronic device expansion frame 200 via the magnets 41, with the bottom housing 11 adhering securely to one side of the electronic device or the electronic device expansion frame 200. This design facilitates wireless charging of the electronic device and allows for easy disassembly.

Furthermore, the wireless charging module 6 is attached to the inner surface of the bottom housing 11, enabling it to be positioned close to the electronic device during use for wireless charging.

Furthermore, positioning holes 16 are provided on the second cover 13, the fan support frame 332, the control circuit board 2, and the first cover 12 in corresponding locations, with positioning pins 17 inserted into these holes. This arrangement allows the second cover 13, the fan support frame 332, the control circuit board 2, and the first cover 12 to be positioned relative to each other, thereby enhancing structural stability.

Furthermore, an air inlet 18 is located on the bottom surface of the first cover 12, while an air outlet 19 is provided on the peripheral side of the first cover 12. Both the air inlet 18 and the air outlet 19 are connected to the first mounting groove 14. When the fan module 33 is operational, air enters the first mounting groove 14 through the peripheral side of the first cover 12 and exits through the bottom surface, carrying the heat generated by the semiconductor chilling plate 311 outside the cooler 100.

Furthermore, a switch button 7 is positioned on the first cover 12, above the control circuit board 2 and connected to the control circuit board 2. When the cooler 100 is fixed and used in conjunction with an electronic device and an electronic device expansion frame 200, the switch button 7 on the first cover 12 is oriented towards the user for convenient pressing and control.

Furthermore, an electronic contact pin 8 is disposed on the control circuit board 2 and one end of the electronic contact pin 8 protrudes outside the housing 1. Referring to FIG. 6, in prior art, to enhance photography, external photographic accessories such as filters 300, light shields, lights, microphones, and power supply handles 400 are commonly used in conjunction with electronic devices during shooting. These accessories are typically mounted on the electronic device expansion frame 200 for use, and the power supply handle supplies power to each accessory through the electronic device expansion frame 200. By incorporating electronic contact pins 8, this application allows the cooler 100 to be electrically interconnected with the electronic device expansion frame 200, enabling it to not only supply power to the electronic device expansion accessories through the frame but also to receive power for the cooler 100 itself from the frame.

Furthermore, positioning protrusions 9 are provided on the housing 1. When the cooler 100 is used with the electronic device expansion frame, the positioning protrusions 9 engage with positioning grooves on the frame, facilitating positioning of both components.

It is emphasized that the aforementioned embodiments serve as preferred illustrations and do not constitute limitations on the scope of the patent claims presented herein. Any structural modifications that are deemed equivalent, based on the disclosure and drawings of this application, or their direct/indirect application in related technical domains, fall within the ambit of patent protection afforded to this application, in line with its underlying concept.

What is claimed is:

1. A cooler, comprising:
a housing, a control circuit board, a cooling component, a connecting piece, and a power supply interface;
wherein the control circuit board and the cooling component are provided within the housing, and the cooling component is connected to the control circuit board; and
wherein the power supply interface is electrically connected to the control circuit board, the power supply interface is provided and exposed on the housing, and the connecting piece is mounted on one side of the housing.

2. The cooler according to claim 1, wherein the cooling component comprises a cooling element and a fan module, and the cooling element and the fan module are both provided within the housing and electrically connected to the control circuit board; and
wherein the cooling element is adjacently positioned to the fan module.

3. The cooler according to claim 2, wherein the connecting piece comprises a plurality of magnets, the plurality of magnets are mounted on one side of the housing for magnetic attraction to an external structure.

4. The cooler according to claim 2, wherein the cooling component further comprises a conductive piece; and
wherein the cooling element comprises a semiconductor chilling plate, and a hot end of the semiconductor chilling plate facing the fan module and a cold end of the semiconductor chilling plate facing the conductive piece.

5. The cooler according to claim 4, wherein the connecting piece comprises a plurality of magnets, the conductive piece comprises a plurality of conductive pieces, and the plurality of magnets and the plurality of conductive pieces are arranged alternately within the housing.

6. The cooler according to claim 2, wherein the fan module comprises a fan and a fan support frame;
wherein the fan is electrically connected to the control circuit board, and the fan support frame is fixedly connected to the housing; and
wherein a mounting position is provided on one side of the fan support frame, and the fan is securely fixed to the mounting position and positioned proximate to the cooling element.

7. The cooler according to claim 6, wherein the control circuit board is fixed at the mounting position, and comprises a bypass through-hole in a center of the control circuit board; and
wherein the fan is provided within the bypass through-hole of the mounting position, enabling the control circuit board to surround a periphery of the fan.

8. The cooler according to claim 7, wherein the housing comprises a cover and a bottom housing, the cover is connected to the bottom housing; and
wherein the fan support frame is connected to the cover.

9. The cooler according to claim 8, wherein the cover comprises a first cover and a second cover, the first cover is connected to the second cover;
wherein the second cover is connected to the bottom housing;
wherein a first mounting groove is formed among the first cover, the fan support frame, and the second cover;
wherein the control circuit board and the fan module are provided within the first mounting groove; and
wherein a second mounting groove is formed among the second cover, the fan support frame, and the bottom housing, housing the cooling element and the connecting piece.

10. The cooler according to claim 9, further comprising a wireless charging module disposed within the second mounting groove,
wherein the wireless charging module is electrically connected to the control circuit board and positioned at a cold end of a semiconductor chilling plate.

11. The cooler according to claim 1, wherein an electronic contact pin is disposed on the control circuit board and one end of the electronic contact pin protrudes outside the housing.

12. The cooler according to claim 10, wherein a positioning protrusion is additionally disposed on the housing.
